(19) United States
(12) Patent Application Publication
(10) Pub. No.: US 2025/0370345 A1
(43) Pub. Date: Dec. 4, 2025

(54) HEAT TREATMENT APPARATUS

(71) Applicant: Samsung Electronics Co., Ltd., Suwon-si (KR)

(72) Inventors: Youngho HWANG, Suwon-si (KR); Jaehong LIM, Suwon-si (KR); Sunyoung YUN, Suwon-si (KR); Chulmin CHO, Suwon-si (KR)

(21) Appl. No.: 19/019,576

(22) Filed: Jan. 14, 2025

(30) Foreign Application Priority Data
May 31, 2024 (KR) 10-2024-0071438

(51) Int. Cl. G03F 7/20; G03F 7/00; H05B 3/00

(52) U.S. Cl. CPC G03F 7/2041; G03F 7/70733; H05B 3/0047

(57) ABSTRACT

A heat treatment apparatus includes a stage having a surface configured to support a substrate, wherein an exposed resist film is formed on the substrate; and a heater spaced apart from the stage in a direction perpendicular to the surface of the stage, wherein the heater is configured such that a relative movement occurs between the stage and the heater that is parallel to the surface of the stage, and the heater is configured to apply heat energy to the substrate in a position at which the heater overlaps with the stage in the direction perpendicular to the surface of the stage during the relative movement between the stage and the heater.

### CROSS-REFERENCE TO RELATED APPLICATION(S)

This application claims the benefit of Korean Patent Application No. 10-2024-0071438, filed on May 31, 2024, in the Korean Intellectual Property Office, the disclosure of which is incorporated herein by reference.

### BACKGROUND

### 1. Field of the Invention

Example embodiments relate to a heat treatment apparatus, and more particularly, to a heat treatment apparatus that may be applied in a heat treatment process after an exposure process in a photolithography process.

### 2. Description of the Related Art

A photolithography process is performed in fabricating a semiconductor device. In the photolithography process, a coating treatment process for coating a substrate such as a semiconductor wafer with a resist such as a photoresist, an exposure process for applying light energy to the coated resist, a heat treatment process for heat-treating the exposed resist to induce a crosslinking reaction, and a development process for treating the crosslinking reaction-induced resist may proceed in sequence. A predetermined resist pattern is formed on a substrate through the photolithography process.

The heat treatment process has an influence on a pattern pitch size of a resist pattern, and a wanted pattern pitch size may be obtained through the control of heat energy and cooling applied to a substrate. Uncontrolled heat energy applied to a substrate may make it difficult to control a pattern pitch size of a resist pattern.

### SUMMARY

An aspect of the invention provides a heat treatment apparatus for controlling a pattern pitch size of a resist pattern by controlling heat energy and cooling applied to a substrate in a heat treatment process of a photolithography process.

The present disclosure is not limited to the technical features described above, and other features may be clearly understood by those skilled in the art from the following description.

According to an aspect, a heat treatment apparatus includes a stage having a surface configured to support a substrate, wherein an exposed resist film is formed on the substrate; and a heater spaced apart from the stage in a direction perpendicular to the surface of the stage, wherein the heater is configured such that a relative movement occurs between the stage and the heater, the relative movement being parallel to the surface of the stage, wherein the heater is configured to apply heat energy to the substrate in a position at which the heater overlaps with the stage in the direction perpendicular to the surface of the stage during the relative movement between the stage and the heater.

According to another aspect, a heat treatment apparatus includes a stage having a surface configured to support a substrate, wherein an exposed resist film is formed on the substrate; a heater spaced apart from the stage in a direction perpendicular to the surface of the stage; and a transfer device configured to cause a relative reciprocating movement between the stage and the heater, wherein the heater is configured such that the relative reciprocating movement occurs between the stage and the heater, the relative reciprocating movement being parallel to the surface of the stage, wherein the relative reciprocating movement includes a first relative movement and a second relative movement in an opposite direction to the first relative movement, and wherein the heater is configured to apply heat energy to the substrate in a position at which the heater overlaps with the stage in the direction perpendicular to the surface of the stage during the relative reciprocating movement between the stage and the heater.

According to another aspect, a heat treatment apparatus includes a stage having a surface configured to support a substrate, wherein an exposed resist film is formed on the substrate; a heater spaced apart from the stage in a direction perpendicular to the surface of the stage, wherein the heater is configured such that a relative reciprocating movement occurs between the stage and the heater, the relative reciprocating movement being in a direction parallel to the surface of the stage; and a cooler spaced apart from the stage in the direction perpendicular to the surface of the stage, the cooler being configured to cool the substrate to which heat energy is applied by the heater during a relative reciprocating movement between the stage and the cooler in the direction parallel to the surface of the stage, wherein the relative reciprocating movement includes a first relative movement and a second relative movement in an opposite direction to the first relative movement, wherein the stage includes a supporting plate equipped with a flow path and a protrusion protruding on the supporting plate, and the supporting plate is configured to circulate a fluid in the flow path that cools the substrate during the second relative movement between the stage and the heater, and the protrusion is configured to support the substrate spaced apart from the supporting plate by a predetermined distance, wherein the heater is configured to apply heat energy to the substrate in a position in which the heater is vertically aligned with the stage during the first relative movement and not to apply heat energy to the substrate during the second relative movement, and wherein the relative reciprocating movement between the stage and the cooler is identical to the relative reciprocating movement between the stage and the heater, wherein the cooler is positioned alongside the heater in the direction parallel to the surface of the stage, and wherein the cooler is configured to cool the substrate in a position at which the cooler overlaps with the stage in the direction perpendicular to the surface of the stage during at least one of the first relative movement and the second relative movement.

According to an aspect, a method of heat treating a substrate includes supporting the substrate on a surface of a stage, wherein an exposed resist film is formed on the substrate; causing a relative movement between the stage and a heater, the relative movement being parallel to the surface of the stage, such that the substrate passes by the heater; using the heater, applying heat to the substrate while the substrate passes by the heater.

Additional aspects of example embodiments will be set forth in part in the description which follows and, in part, will be apparent from the description or may be learned by practice of the disclosure.

According to example embodiments, it is possible for a heat treatment apparatus to control a pattern pitch size of a resist pattern by controlling heat energy and cooling applied to a substrate in a heat treatment process of a photolithography process.

Additional features and advantages of the disclosure will be set forth in the description which follows, and in part will be apparent from the description, or may be learned by practice of the disclosure. The objectives and other advantages of the disclosure will be realized and attained by the structure particularly pointed out in the written description and claims hereof as well as the appended drawings.

### BRIEF DESCRIPTION OF THE DRAWINGS

The drawings of the present disclosure are shown according to example embodiments, and a ratio of width, length, or height (or thickness) of each element is to describe the present disclosure in detail and the ratio may be different from the actual ratio. Further, in a coordinate system shown in the drawings, each axis may be perpendicular to one another, and a direction pointed by an arrow may be + direction and a directly opposite direction (a direction turned by 180 degrees) to the direction pointed by the arrow may be − direction.

These and/or other aspects, features, and advantages of the invention will become apparent and more readily appreciated from the following description of example embodiments, taken in conjunction with the accompanying drawings of which:

FIG. 1 is a top view illustrating a heat treatment apparatus according to a first example embodiment of the present disclosure and showing a state before a substrate passes a heating part and a cooling part;

FIG. 2 is a side view illustrating the heat treatment apparatus according to the first example embodiment of the present disclosure and showing a state before a substrate passes a heating part and a cooling part;

FIG. 3 is a top view illustrating the heat treatment apparatus according to the first example embodiment of the present disclosure and showing a state while a substrate passes a heating part and a cooling part;

FIG. 4 is a side view illustrating the heat treatment apparatus according to the first example embodiment of the present disclosure and showing a state while a substrate passes a heating part and a cooling part;

FIG. 5 is a top view illustrating the heat treatment apparatus according to the first example embodiment of the present disclosure and showing a state after a substrate passes a heating part and a cooling part;

FIG. 6 is a side view illustrating the heat treatment apparatus according to the first example embodiment of the present disclosure and showing a state after a substrate passes a heating part and a cooling part;

FIG. 7 is a top view illustrating the heat treatment apparatus according to the first example embodiment of the present disclosure and showing a state before a substrate repasses a heating part and a cooling part;

FIG. 8 is a side view illustrating the heat treatment apparatus according to the first example embodiment of the present disclosure and showing a state before a substrate repasses a heating part and a cooling part;

FIG. 9 is a top view illustrating the heat treatment apparatus according to the first example embodiment of the present disclosure and showing a state while a substrate repasses a heating part and a cooling part;

FIG. 10 is a side view illustrating the heat treatment apparatus according to the first example embodiment of the present disclosure and showing a state while a substrate repasses a heating part and a cooling part;

FIG. 11 is a top view illustrating the heat treatment apparatus according to the first example embodiment of the present disclosure and showing a state after a substrate repasses a heating part and a cooling part;

FIG. 12 is a side view illustrating the heat treatment apparatus according to the first example embodiment of the present disclosure and showing a state after a substrate repasses a heating part and a cooling part;

FIG. 13 is a graph showing a temperature at each time point after passing and repassing a heating part and a cooling part for any one point on a substrate surface in the first example embodiment of the present disclosure;

FIG. 14 is a graph showing a temperature at each time point when passing and repassing a heating part and a cooling part are alternatingly executed a plurality of times for any one point on a substrate surface;

FIG. 15 is a top view illustrating a heat treatment apparatus according to a second example embodiment of the present disclosure and showing a state before a substrate passes a heating part and a cooling part;

FIG. 16 is a top view illustrating the heat treatment apparatus according to the second example embodiment of the present disclosure and showing a state while a substrate passes a heating part and a cooling part;

FIG. 17 is a top view illustrating the heat treatment apparatus according to the second example embodiment of the present disclosure and showing a state after a substrate passes a heating part and a cooling part;

FIG. 18 is a top view illustrating the heat treatment apparatus according to the second example embodiment of the present disclosure and showing a state before a substrate repasses a heating part and a cooling part;

FIG. 19 is a top view illustrating the heat treatment apparatus according to the second example embodiment of the present disclosure and showing a state while a substrate repasses a heating part and a cooling part;

FIG. 20 is a top view illustrating the heat treatment apparatus according to the second example embodiment of the present disclosure and showing a state after a substrate repasses a heating part and a cooling part;

FIG. 21 is a top view illustrating a heat treatment apparatus according to a third example embodiment of the present disclosure and showing a state before a substrate passes a heating part and a cooling part;

FIG. 22 is a side view illustrating the heat treatment apparatus according to the third example embodiment of the present disclosure and showing a state before a substrate passes a heating part and a cooling part;

FIG. 23 is a top view illustrating the heat treatment apparatus according to the third example embodiment of the present disclosure and showing a state while a substrate passes a heating part and a cooling part;

FIG. 24 is a side view illustrating the heat treatment apparatus according to the third example embodiment of the present disclosure and showing a state while a substrate passes a heating part and a cooling part;

FIG. 25 is a top view illustrating the heat treatment apparatus according to the third example embodiment of the present disclosure and showing a state after a substrate passes a heating part and a cooling part;

FIG. 26 is a side view illustrating the heat treatment apparatus according to the third example embodiment of the present disclosure and showing a state after a substrate passes a heating part and a cooling part;

FIG. 27 is a top view illustrating the heat treatment apparatus according to the third example embodiment of the present disclosure and showing a state before a substrate repasses a heating part and a cooling part;

FIG. 28 is a side view illustrating the heat treatment apparatus according to the third example embodiment of the present disclosure and showing a state before a substrate repasses a heating part and a cooling part;

FIG. 29 is a top view illustrating the heat treatment apparatus according to the third example embodiment of the present disclosure and showing a state while a substrate repasses a heating part and a cooling part;

FIG. 30 is a side view illustrating the heat treatment apparatus according to the third example embodiment of the present disclosure and showing a state while a substrate repasses a heating part and a cooling part;

FIG. 31 is a top view illustrating the heat treatment apparatus according to the third example embodiment of the present disclosure and showing a state after a substrate repasses a heating part and a cooling part;

FIG. 32 is a side view illustrating the heat treatment apparatus according to the third example embodiment of the present disclosure and showing a state after a substrate repasses a heating part and a cooling part;

FIG. 33 illustrates a supporting device according to an example embodiment of the present disclosure;

FIG. 34 is a top view illustrating a heat treatment apparatus according to a fourth example embodiment of the present disclosure and showing a state before a substrate repasses a heating part and a cooling part;

FIG. 35 is a top view illustrating the heat treatment apparatus according to the fourth example embodiment of the present disclosure and showing a state while a substrate repasses a heating part and a cooling part;

FIG. 36 is a side view illustrating the heat treatment apparatus according to the fourth example embodiment of the present disclosure and showing a state while a substrate repasses a heating part and a cooling part;

FIG. 37 is a top view illustrating the heat treatment apparatus according to the fourth example embodiment of the present disclosure and showing a state after a substrate repasses a heating part and a cooling part;

FIG. 38 is a side view illustrating the heat treatment apparatus according to the fourth example embodiment of the present disclosure and showing a state after a substrate repasses a heating part and a cooling part; and

FIG. 39 is a graph showing a temperature at each time point after passing and repassing a heating part and a cooling part for any one point on a substrate surface in the fourth example embodiment of the present disclosure.

FIG. 40 shows a method of heat treating a substrate according to an example embodiment.

### DETAILED DESCRIPTION

Before describing the present disclosure in detail, the words and terminologies used in the specification and claims may not be construed as limited to common or dictionary meanings. In addition, the words and terminologies may be construed as meanings and conceptions coinciding with the technical spirit of the present disclosure under a principle that the inventor(s) may appropriately define the conception of the terminologies to explain the invention in an optimum manner. The example embodiments described in the specification and the configurations illustrated in the drawings are no more than the most preferred example embodiments of the present disclosure and may not fully cover the spirit of the present disclosure. Therefore, there may be various equivalents and modifications that may replace those when this application is filed.

Like reference numerals in each drawing attached to the specification may refer to components or elements performing like functions in substance. For convenience of description and understanding, the same reference numeral may be used for description in different example embodiments. In other words, although elements with the same reference numeral are illustrated in a plurality of drawings, all of the plurality of drawings may not represent one example embodiment.

When an element is referred to as being “on” or “connected to” another element in the specification, it may be understood that the element may be directly on or directly connected to another element, without any intervening elements therebetween, or an intervening element may be present in between.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

An item, layer, or portion of an item or layer described as “extending” or as extending “lengthwise” in a particular direction has a length in the particular direction and a width perpendicular to that direction, where the length is greater than the width.

Terms such as “same,” “equal,”, “identical,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Further, when an element is referred to as being “above” another element in the specification, it may be understood that the element is present above based on a vertical direction or, for example, above based on +z direction in a drawing, and it may be understood that the element may be in contact with or directly connected to another element or an intervening element may be present in between. When an element is referred to as being “on” another element in the specification may also be similarly understood.

Further, when an element is referred to as being “below” another element in the specification, it may be understood that the element is present below based on a vertical direction or, for example, below based on −z direction in a drawing, and it may be understood that the element may be in contact with or directly connected to another element or an intervening element may be present in between. When an element is referred to as being “under” another element in the specification may also be similarly understood.

Further, when an element is referred to as being “directly on,” “contacting,” or “in contact with” another element in the specification, it may be understood that there are no intervening elements present. Other similar expressions describing position relationships between elements may also be similarly construed as above.

In the descriptions below, a singular expression includes a plural expression unless apparently otherwise stated. It may be understood that terms such as “comprise”, “include”, and “consist of” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

Further, in the descriptions below, expressions such as upper side, upper surface, lower side, lower surface, side surface, front surface, and rear surface are represented based on directions illustrated in a drawing and may be differently represented when the direction of a corresponding object changes.

Further, terms including ordinal numbers such as “first” and “second” may be used to differentiate between elements in the specification and claims. These ordinal numbers may be used to differentiate identical or similar elements from each other, and the use of the ordinal numbers may not limit the meanings of terms. As an example, an element combined with an ordinal number is not to be construed to mean that the using order or arrangement order thereof is limited by the number. In some cases, each ordinal number may also be used by replacing each other.

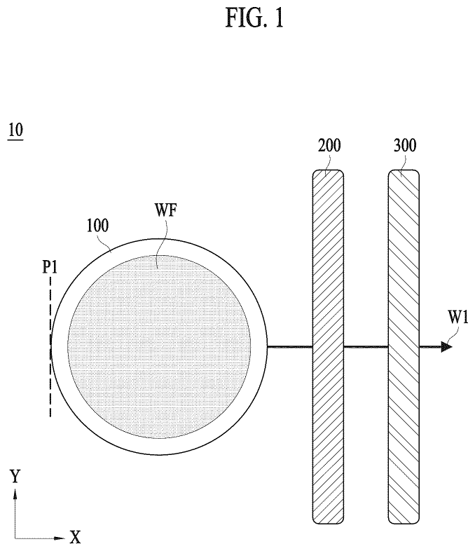

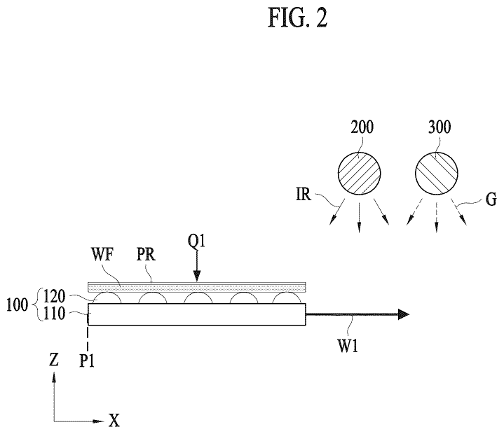

FIG. 1 is a top view illustrating a heat treatment apparatus 10 according to a first example embodiment of the present disclosure and showing a state before a substrate WF passes (e.g., underneath) a heating part 200 and a cooling part 300 (e.g., a cooler). FIG. 2 is a side view illustrating the heat treatment apparatus 10 according to the first example embodiment of the present disclosure and showing a state before the substrate WF passes the heating part 200 and the cooling part 300.

The heat treatment apparatus 10 according to an example embodiment of the present disclosure may be applied in a heat treatment process after an exposure process in a photolithography process. The heat treatment apparatus 10 may induce a crosslinking reaction of an exposed resist film PR formed on the substrate WF.

In an example, a resist included in the resist film PR may be a chemically amplified resist (CAR) for generating a hydrogen ion (H⁺, photo acid) in an exposure process. The hydrogen ion generated in the exposure process may change the structure of the resist in a heat treatment process, and a change of the structure changes the solubility of the resist. In addition, the hydrogen ion generated in the exposure process may influence a resist film of an unexposed area by diffusion, thereby degrading a resist pattern. Therefore, resist pattern degradation may be improved through an appropriate treatment in the heat treatment process. Further, in an example, resists used in the art may be applied to the resist included in the resist film PR in addition to the CAR.

The heat treatment apparatus 10 according to an example embodiment of the present disclosure may control heat energy and cooling applied to the substrate WF to, in turn, control a pattern pitch size of a resist pattern and minimize degradation.

The heat treatment apparatus 10 according to an example embodiment of the present disclosure may include a supporting device 100 (e.g., a stage) which supports the substrate WF where the exposed resist film PR is formed. The supporting device 100 may include a supporting plate 110. The supporting plate 110 may have a shape identical to the substrate WF and, for example, may have a circular plate shape. a surface of the supporting plate 110 supporting the substrate may be equal to or larger than one surface of the substrate WF in area.

The supporting device 100 according to an example embodiment of the present disclosure may include a protrusion 120 protruding on the supporting plate 110. The substrate WF may be supported on the protrusion 120 and spaced apart from the supporting plate 110 by a predetermined distance. In addition, a plurality of the protrusions 120 may be arranged. Further, so that the substrate WF may be supported on the protrusion 120 in parallel with the supporting plate 110, the plurality of the protrusions 120 may be appropriately positioned or arranged on the supporting plate 110.

The supporting device 100 according to an example embodiment of the present disclosure may further include a transfer device (not shown) so as to be movable. The transfer device may include, for example, a motor and/or an actuator.

The movement of the supporting device may be controlled by a controller. Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The heat treatment apparatus 10 according to an example embodiment of the present disclosure may include the heating part 200 (e.g., heater) spaced apart in a direction perpendicular to a surface of the supporting device 100 supporting the substrate WF and disposed in a direction of a relative movement between the supporting device 100 and the heating part 200, the relative movement being parallel to the surface of the supporting device 100 supporting the substrate WF. The relative movement between the supporting device 100 and the heating part 200 may cause the heating part 200 to be above the supporting device 100, to one side of the supporting device 100, and to the other side of the supporting device 100 in the direction of the relative movement. The relative movement between the supporting device 100 and the heating part 200 may be controlled by the controller.

The heating part 200 according to an example embodiment of the present disclosure may apply heat energy to the substrate WF in a position at which the heating part overlaps with the supporting device 100 in the direction perpendicular to the surface of the supporting device 100 supporting the substrate WF during the relative movement between the supporting device 100 and the heating part 200.

The heating part 200 according to an example embodiment of the present disclosure may be turned on or turned off. In addition, the heating part 200 may emit infrared light IR when turned on and may determine an energy amount of the infrared light IR by adjusting an output. The infrared light IR may have a wavelength between about 850 nanometers (nm) and 1000 nm to efficiently transfer heat energy to the substrate WF composed of silicon (Si) to improve temperature on a surface of the substrate WF. For example, the heating part 200 may include, but is not limited to, a light-emitting diode (LED) device emitting the infrared light IR. The on/off state of the heating part 200 and the energy amount of the infrared light IR output by the heating part 200 may be controlled by the controller.

The heating part 200 according to an example embodiment of the present disclosure may be formed longer than a diameter of the substrate WF in a direction perpendicular to a direction of moving relative to the supporting device 100. More specifically, the heating part 200 may extend parallel to a surface of the supporting device 100 and may be shaped as a straight line or a curve formed extending to intersect the direction of moving relative to the supporting device 100. Accordingly, when the heating part 200 applies heat energy to the substrate WF in the position of overlapping with the supporting device 100, the heat energy may be applied throughout the substrate WF even though the substrate WF passes the heating part 200 only once. In addition, an entire area of the substrate WF may be evenly heated when a constant speed of the supporting device 100 moving relative to the heating part 200 is maintained, and a degree of heating may also vary for each area of the substrate WF by controlling the speed of the supporting device 100. The heating part may be formed of, for example, a light bar on which one or more LEDs and/or lasers are mounted.

In an example embodiment of the present disclosure, the relative movement of the supporting device 100 and the heating part 200 may continue at least until heat energy by the heating part 200 is applied to an entire area of the exposed resist film PR. For example, at least one of the supporting device 100 and the heating part 200 may move relative to the other one of the supporting device 100 and the heating part 200 such that heat energy by the heating part 200 is applied to an entire area of the exposed resist film PR on the substrate WF.

The heating part 200 according to an example embodiment of the present disclosure may cause a gradual increase in an area to which heat energy is applied in the substrate WF while moving relative to the supporting device 100. In an example, the relative movement of the supporting device 100 and the heating part 200 may continue at least until heat energy by the heating part 200 is applied to an entire area of the exposed resist film PR as the area to which heat energy is applied in the substrate WF gradually increases.

The heating part 200 according to an example embodiment of the present disclosure may further include a transfer device (not shown) so as to be movable. For example, the transfer device may be configured to cause the relative movement of the supporting device 100 and the heating part 200 to continue at least until heat energy by the heating part 200 is applied to an entire area of the exposed resist film PR. The transfer device may be included in the supporting device 100 or in the heating part 200, or a transfer device may be included in each of the supporting device 100 and the heating part 200 to cause the relative movement. The transfer device may be formed of, for example, a motor and/or an actuator to move the supporting device 100 and/or the heating part 200. The transfer device may be controlled by the controller.

The heat treatment apparatus 10 according to an example embodiment of the present disclosure may include a cooling part 300 spaced apart in the direction perpendicular to the surface of the supporting device 100 supporting the substrate WF and configured to cool the substrate WF to which heat energy is (e.g., has been) applied by the heating part 200 while a relative movement between the supporting device 100 and the cooling part 300 occurs in the direction parallel to the surface of the supporting device 100 supporting the substrate WF.

The cooling part 300 according to an example embodiment of the present disclosure may cool the substrate WF to which heat energy is previously applied. In other words, the cooling part 300 may not cool the substrate WF to which heat energy is not applied. The cooling part 300 may reduce a surface temperature of the substrate WF, slow a rising speed of the surface temperature of the substrate WF, or adjust the surface temperature of the substrate WF to be maintained to a constant temperature by cooling the substrate WF to which heat energy is previously applied.

The cooling part 300 according to an example embodiment of the present disclosure may cool the substrate WF in a position at which the cooling part 300 overlaps with the supporting device 100 in the direction perpendicular to the surface of the supporting device 100 supporting the substrate WF during relative movement between the supporting device 100 and the cooling part 300.

The cooling part 300 according to an example embodiment of the present disclosure may cool the substrate WF by spraying gas G. The cooling part 300 may spray or not spray the gas G and may include a pump (not shown) for spraying the gas G. The cooling part 300 may spray or not spray the gas G by adjusting an output of the pump and may adjust a flow. The gas G may include any gas capable of cooling the exposed resist film PR while minimizing a physical or chemical change of the exposed resist film PR. For example, the gas G may be formed of or include but is not limited to, nitrogen (N₂), helium (He), and air.

The cooling part 300 according to an example embodiment of the present disclosure may be formed longer than a diameter of the substrate WF in a direction perpendicular to a direction of moving relative to the supporting device 100. More specifically, the cooling part 300 may extend parallel to a surface of the supporting device 100 and may be shaped as a straight line or a curve formed extending to intersect the direction of moving relative to the supporting device 100. Accordingly, when the cooling part 300 cools the substrate WF in the position of overlapping with the supporting device 100, the substrate WF to which heat energy is applied may be cooled throughout even though the substrate WF passes the cooling part 300 only once. In addition, an entire area of the substrate WF may be evenly cooled when a constant speed of the supporting device 100 moving relative to the cooling part 300 is maintained, and a degree of cooling may also vary for each area of the substrate WF by adjusting the speed of the supporting device 100. For example, the cooling part 300 may include one or more spray nozzles configured to spray the gas G toward the substrate WF to cool the substrate WF. The spray nozzles may be arranged in a straight line or a curved line extending to intersect the direction of moving relative to the supporting device 100. The on/off state and/or the amount of the gas G supplied by the cooling part 300 may be controlled by the controller.

In an example embodiment of the present disclosure, the relative movement of the supporting device 100 and the cooling part 300 may continue at least until an entire area of the exposed resist film PR is cooled by the cooling part 300. For example, at least one of the supporting device 100 and the cooling part 300 may move relative to the other one of the supporting device 100 and the cooling part 300 such that an entire area of the exposed resist film PR is cooled by the cooling part 300.

The cooling part 300 according to an example embodiment of the present disclosure may cause a gradual increase in a cooled area of the substrate WF while moving relative to the supporting device 100. In an example, the relative movement of the supporting device 100 and the cooling part 300 may continue at least until an entire area of the exposed resist film PR is cooled by the cooling part 300 as the cooled area of the substrate WF gradually increases.

The cooling part 300 according to an example embodiment of the present disclosure may perform an identical relative movement to the relative movement of the heating part 200. In other words, the relative movement of the supporting device 100 and the heating part 200 and the relative movement of the supporting device 100 and the cooling part 300 may be identically performed. For example, when the supporting device 100 moves and the heating part 200 is stopped, the cooling part 300 may also be stopped.

The cooling part 300 according to an example embodiment of the present disclosure may be positioned alongside the heating part 200. In addition, the cooling part 300 may be spaced apart from the heating part 200 in a direction of the relative movement by a predetermined distance.

A plurality of the cooling parts 300 according to an example embodiment of the present disclosure may be provided. For example, the heating part 200 may be positioned between the plurality of the cooling parts 300. Some of the cooling parts 300 may be disposed in front of the heating part 200 in the direction of the relative movement and others may be disposed behind the heating part 200 in the direction of the relative movement. In an example embodiment, a first cooling part 300 may be positioned in front of the heating part 200 and a second cooling part 300 may be positioned behind the heating part 200 in the direction of the relative movement.

The cooling part 300 according to an example embodiment of the present disclosure may further include a transfer device (not shown) so as to be movable. The transfer device may be formed of or include, for example, a motor and/or an actuator. The relative movement between the supporting device and the cooling part 300 may be controlled by the controller.

Meanwhile, in the heat treatment apparatus 10 according to an example embodiment of the present disclosure, the supporting device 100 and the heating part 200 may move relative to each other. For example, the supporting device 100 may move and the heating part 200 may not move. In addition, the supporting device 100 may not move and the heating part 200 may move. Further, both the supporting part 100 and the heating part 200 may move. Further, in the heat treatment apparatus 10, the supporting device 100 and the heating part 200 may move relative to each other to overlap with each other in a vertical direction (e.g., when viewed in plan view).

Hereinafter, through FIGS. 1 to 12, the heat treatment apparatus 10 according to the first example embodiment in which the supporting device 100 moves and the heating part 200 and the cooling part 300 do not move is described as one example of a relative movement.

In an example, the substrate WF may be supported on the supporting device 100 in the heat treatment apparatus 10. Specifically, the supporting device 100 may include the supporting plate 110 and the protrusion 120 protruding on the supporting plate 110, and the substrate WF may be supported on the protrusion 120. In addition, the substrate WF may be spaced apart from the supporting plate 110 by a predetermined distance due to the protrusion 120.

In an example, the supporting device 100 may move in the direction parallel to the surface supporting the substrate WF where the exposed resist film PR is formed. The heat treatment apparatus 10 may include the heating part 200 and the cooling part 300 disposed in the direction where the supporting device 100 moves, and here the heating part 200 and the cooling part 300 may be stopped (e.g., in a fixed position). Accordingly, the supporting device 100 may move relative to the heating part 200 and the cooling part 300, and the relative movement of this case may be referred to as a first relative movement W1 (see, e.g., FIGS. 1-4). The supporting device 100 may perform the first relative movement W1 in an x-axis direction which is the direction parallel to the surface supporting the substrate WF from position P1 of an edge thereof.

In an example, the heating part 200 may be in a turned-on state during the first relative movement W1 of the supporting device 100. The turned-on heating part 200 may apply heat energy to the substrate WF in a position in which the heating part 200 overlaps with the supporting device 100.

In an example, the cooling part 300 may be in a state of spraying the gas G during the first relative movement W1 of the supporting device 100. The cooling part 300 spraying the gas G may cool the substrate WF in a position in which the cooling part 300 overlaps with the supporting device 100. Meanwhile, as the cooling part 300 cools the substrate WF, a degree of a temperature increase may be lowered to prevent an excessive rise in the temperature of a surface of the substrate WF or a temperature increase of the surface of the substrate WF may be stopped and maintained.

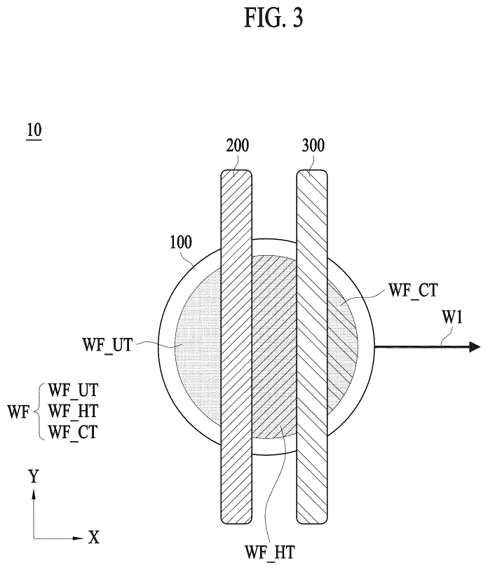

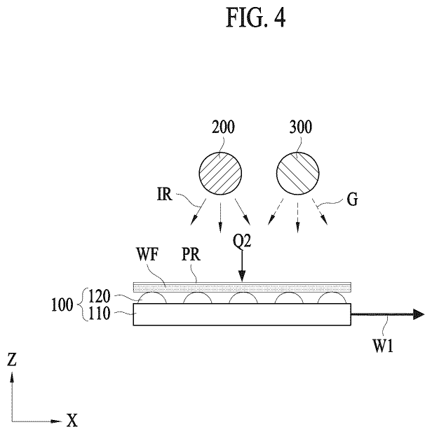

FIG. 3 is a top view illustrating the heat treatment apparatus 10 according to the first example embodiment of the present disclosure and showing a state while the substrate WF passes (e.g., underneath) the heating part 200 and the cooling part 300. FIG. 4 is a side view illustrating the heat treatment apparatus 10 according to the first example embodiment of the present disclosure and showing a state while the substrate WF passes the heating part 200 and the cooling part 300.

In an example, the supporting device 100 supporting the substrate WF may pass the heating part 200. The heating part 200 may apply heat energy to the substrate WF. The heating part 200 may gradually increase an area to which heat energy is applied in the substrate WF during the first relative movement W1. In addition, the supporting device 100 after passing the heating part 200 may pass the cooling part 300. The cooling part 300 may cool the substrate WF to which heat energy is applied by the heating part 200. The cooling part 300 may gradually increase a cooled area in the substrate WF to which heat energy is previously applied by the heating part 200 during the first relative movement W1.

In an example, while the supporting device 100 performs the first relative movement W1 with respect to the heating part 200 and the cooling part 300, the substrate WF may be divided into a cooled portion WF_CT that has passed both the heating part 200 and the cooling part 300, a heated portion WF_HT that has passed the heating part 200 alone, and an untreated portion WF_UT that has not yet reached the heating part 200 and the cooling part 300.

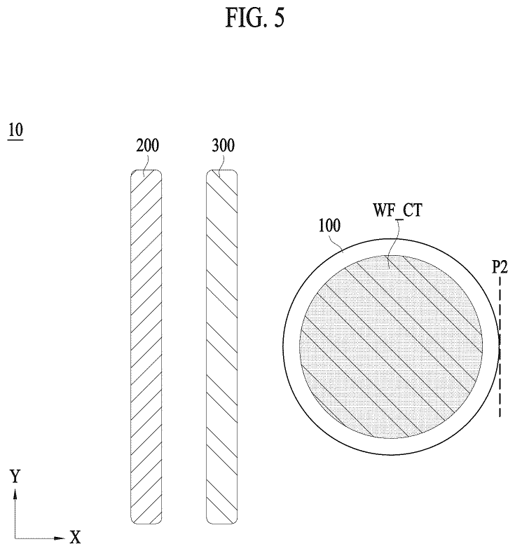

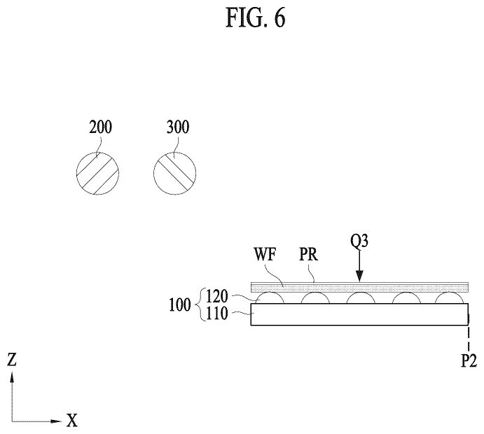

FIG. 5 is a top view illustrating the heat treatment apparatus 10 according to the first example embodiment of the present disclosure and showing a state after the substrate WF passes the heating part 200 and the cooling part 300. FIG. 6 is a side view illustrating the heat treatment apparatus 10 according to the first example embodiment of the present disclosure and showing a state after the substrate WF passes the heating part 200 and the cooling part 300.

In an example, the supporting device 100 may perform the first relative movement W1 in the x-axis direction which is a direction parallel to a surface supporting the substrate WF at least until an entire area of the exposed resist film PR formed on the substrate WF passes the heating part 200 and the cooling part 300 and an edge thereof reaches position P2. In an embodiment, the first relative movement W1 here may correspond to a movement in which the supporting device 100 moves from a position in which an edge of the supporting device 100 is aligned with position P1 (see, e.g., FIG. 1) to a position in which an opposite edge of the supporting device 100 is aligned with position P2 (see, e.g., FIG. 5).

Specifically, the first relative movement W1 of the supporting device 100 and the heating part 200 may continue at least until heat energy by the heating part 200 is applied to the entire area of the exposed resist film PR. In addition, the first relative movement W1 of the supporting device 100 and the cooling part 300 may continue at least until the entire area of the exposed resist film PR is cooled by the cooling part 300.

In an example, when the edge of the supporting device 100 reaches position P2 through the process described above, the supporting device 100 may stop the first relative movement W1 with respect to the heating part 200 and the cooling part 300. When the first relative movement W1 is stopped, the heating part 200 may become in a turned-off state, and the cooling part 300 may become in a state of not spraying the gas G.

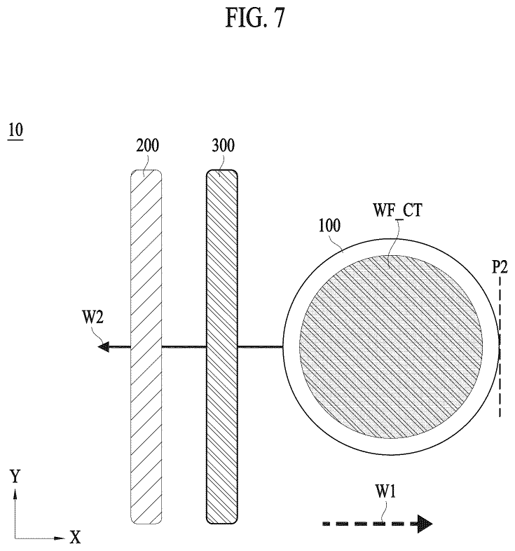

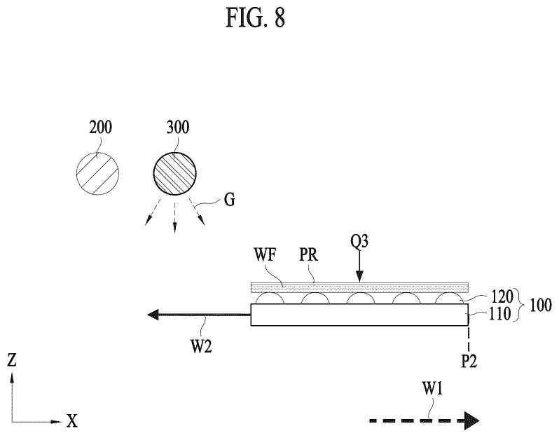

FIG. 7 is a top view illustrating the heat treatment apparatus 10 according to the first example embodiment of the present disclosure and showing a state before the substrate WF repasses the heating part 200 and the cooling part 300. FIG. 8 is a side view illustrating the heat treatment apparatus 10 according to the first example embodiment of the present disclosure and showing a state before the substrate WF repasses the heating part 200 and the cooling part 300.

In an example, the supporting device 100 may perform a second relative movement W2 in an opposite direction to the first relative movement W1. As the supporting device 100 performs the first relative movement W1 and then the second relative movement W2 in the opposite direction, the supporting device 100 may perform a relative reciprocating movement W1 and W2 with respect to the heating part 200 and the cooling part 300. In other words, the relative reciprocating movement W1 and W2 may include the first relative movement W1 and the second relative movement W2. For example, as the supporting device 100 moves and the heating part 200 and the cooling part 300 are stopped, the supporting device 100 may perform the second relative movement W2 in a −x-axis direction which is opposite to a +x-axis direction, the direction of the first relative direction W1. Meanwhile, the second relative movement W2 may correspond to a movement in which the supporting device 100 moves from a position in which an edge of the supporting device 100 is aligned with position P2 to a position in which an opposite edge of the supporting device is aligned with position P1.

In an example, the heating part 200 of this case may be in a turned-off state during the second relative movement W2 to the supporting device 100. The turned-off heating part 200 may not apply heat energy to the substrate WF supported by the supporting device 100.

In an example, the cooling part 300 may be in a state of spraying the gas G during the second relative movement W2 to the supporting device 100. The cooling part 300 spraying the gas G may cool the substrate WF in a position in which the cooling part 300 overlaps with the supporting device 100. Meanwhile, the cooling part 300 of this case may cool the substrate WF to lower a surface temperature of the substrate WF. In other words, the cooling part 300 may cool the substrate WF in a position of overlapping with the supporting device 100 in a direction perpendicular to a surface of the supporting device 100 supporting the substrate WF during at least one of the first relative movement W1 and the second relative movement W2.

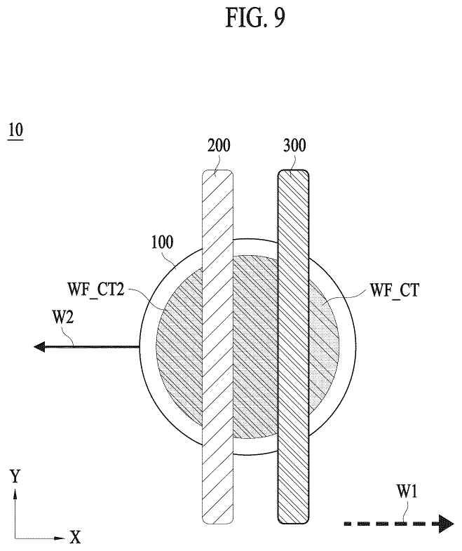

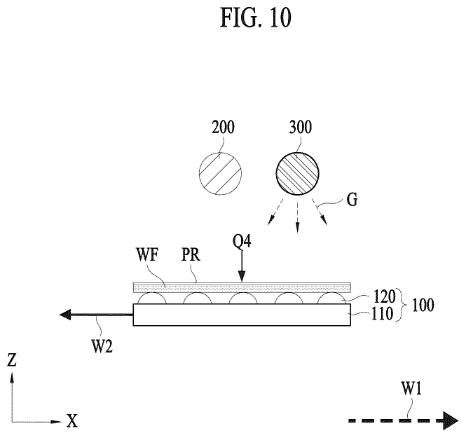

FIG. 9 is a top view illustrating the heat treatment apparatus 10 according to the first example embodiment of the present disclosure and showing a state while the substrate WF repasses the heating part 200 and the cooling part 300. FIG. 10 is a side view illustrating the heat treatment apparatus 10 according to the first example embodiment of the present disclosure and showing a state while the substrate WF repasses the heating part 200 and the cooling part 300.

In an example, the supporting device 100 supporting the substrate WF may pass the cooling part 300. The cooling part 300 may cool the substrate WF. The cooling part 300 may gradually increase a cooled area in the substrate WF to which heat energy is previously applied by the heating part 200 during the second relative movement W2. In addition, the supporting device 100 after passing the cooling part 300 may pass the heating part 200, and the heating part 200 in the turned-off state may not apply heat energy to the substrate WF.

In an example, while the supporting device 100 performs the second relative movement W2 with respect to the heating part 200 and the cooling part 300, the substrate WF may be divided into the cooled portion WF_CT that has been cooled by the cooling part 300 after the heating part 200 applies heat energy during the first relative movement W1 and an additionally cooled portion WF_CT2 that has been twice cooled by the cooling part 300.

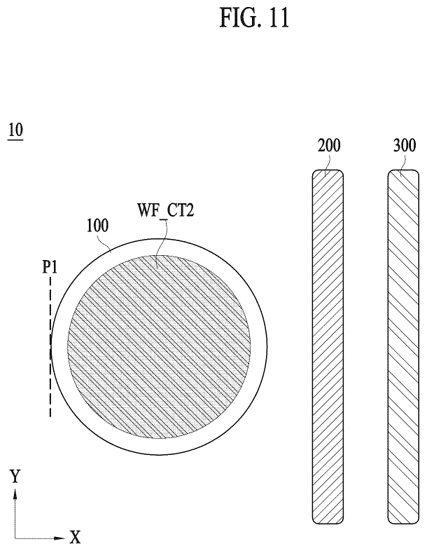

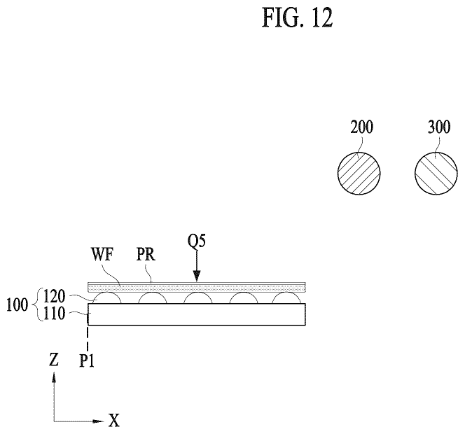

FIG. 11 is a top view illustrating the heat treatment apparatus 10 according to the first example embodiment of the present disclosure and showing a state after the substrate WF repasses the heating part 200 and the cooling part 300. FIG. 12 is a side view illustrating the heat treatment apparatus 10 according to the first example embodiment of the present disclosure and showing a state after the substrate WF repasses the heating part 200 and the cooling part 300.

In an example, the supporting device 100 may perform the second relative movement W2 in the x-axis direction which is a direction parallel to a surface supporting the substrate WF at least until an entire area of the exposed resist film PR formed on the substrate WF repasses the heating part 200 and the cooling part 300 and an edge thereof reaches position P1.

Specifically, the second relative movement W2 of the supporting device 100 and the cooling part 300 may continue at least until the entire area of the exposed resist film PR is cooled by the cooling part 300.

In an example, when the edge of the supporting device 100 reaches position P1 through the process described above, the supporting device 100 may stop the second relative movement W2 with respect to the heating part 200 and the cooling part 300. When the second relative movement W2 is stopped, the heating part 200 may maintain the turned-off state, and the cooling part 300 may become in a state of not spraying the gas G.

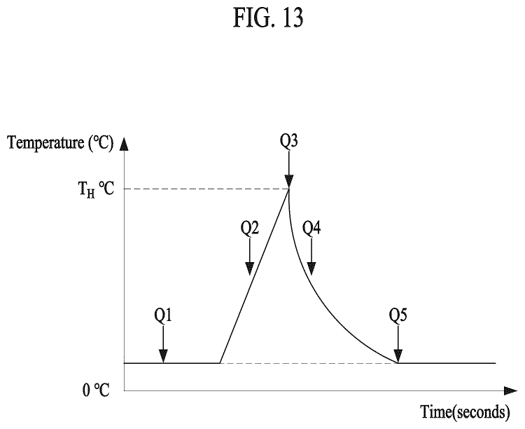

FIG. 13 may be a graph showing a temperature at each time point after passing and repassing the heating part 200 and the cooling part 300 for any one point on a substrate WF surface in the first example embodiment of the present disclosure and may be a graph showing, for example, a center point temperature of the substrate WF surface.

Referring to FIG. 13, the points Q1 to Q5 represent temperatures of a point on the substrate WF at different points in time while the substrate WF passes and repasses the heating part 200 and the cooling part 300. Q1 represents any one point on the surface in a state before the substrate WF passes the heating part 200 and the cooling part 300 (see FIG. 2). Q2 represents any one point on the surface in a state while the substrate WF passes the heating part 200 and the cooling part 300 (see FIG. 4). Q3 represents any one point on the surface in a state after the substrate WF passes the heating part 200 and the cooling part 300 (see FIG. 6). Q4 represents any one point on the surface in a state while the substrate WF repasses the heating part 200 and the cooling part 300 (see FIG. 10). Q5 represents any one point on the surface in a state after the substrate WF repasses the heating part 200 and the cooling part 300 (see FIG. 12).

Referring to FIG. 13, T_{H} represents a temperature that may be determined based on a characteristic of an exposed resist and may be about 70° C. to 150° C. or 80° C. to 130° C. The surface of the substrate WF may reach up to temperature T_{H} while the substrate WF performs the first relative movement W1 to the heating part 200 and the cooling part 300, and the surface of the substrate WF may be cooled while the substrate WF performs the second relative movement W2 to the heating part 200 and the cooling part 300. When increasing the surface temperature of the substrate WF, a degree of a temperature increase may be controlled by adjusting a wavelength of the infrared light IR or an output from the heating part 200 and/or adjusting a temperature or a flow of the gas G from the cooling part 300. In addition, when decreasing the surface temperature of the heated substrate WF, a degree of a temperature decrease may be controlled by adjusting the temperature or the flow of the gas G from the cooling part 300. Accordingly, a pattern pitch size of a resist pattern may be controlled.

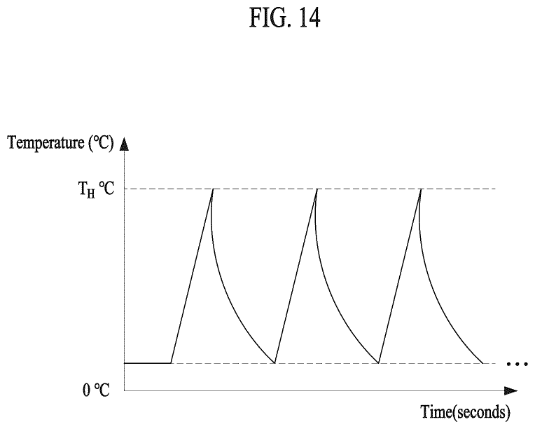

FIG. 14 may be a graph showing a temperature at each time point when the relative reciprocating movement (e.g., passing and repassing the heating part 200 and the cooling part 300) is repeatedly executed a plurality of times for any one point on a substrate WF surface and may be a graph showing, for example, a center point temperature of the substrate WF surface.

The relative reciprocating movement of the supporting device 100 and the heating part 200 according to an example embodiment of the present disclosure may be executed with alternating directions a plurality of times. In addition, the relative reciprocating movement of the supporting device 100 and the cooling part 300 may be similarly executed with alternating directions a plurality of times. Referring to FIG. 14, when the relative reciprocating movement is performed once, a temperature change on the substrate WF surface may occur as in the graph of FIG. 13, and when the relative reciprocating movement is performed two times or more, a form repeating the graph of FIG. 13 may occur. Through this, a pattern pitch size of a resist pattern may be controlled.

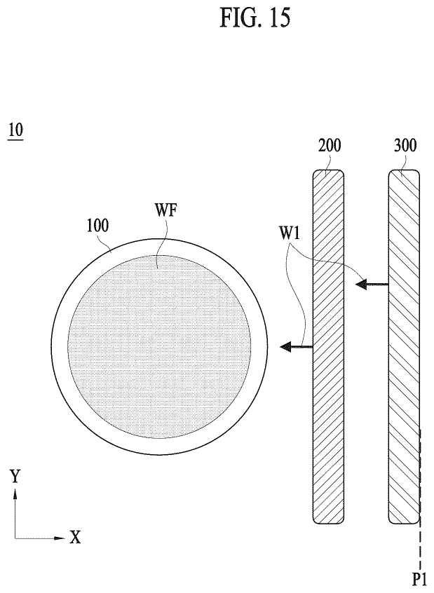

Hereinafter, through FIGS. 15 to 20, the heat treatment apparatus 10 according to a second example embodiment in which the supporting device 100 does not move and the heating part 200 and the cooling part 300 move is described as one example of a relative movement. Describing here may refer to the descriptions above of the heat treatment apparatus 10 according to the first example embodiment unless contradicted.

FIG. 15 is a top view illustrating the heat treatment apparatus 10 according to the second example embodiment of the present disclosure and showing a state before the substrate WF passes the heating part 200 and the cooling part 300 (e.g., before the heating part 200 and the cooling part 300 pass the substrate WF).

In an example, the heating part 200 and the cooling part 300 may move in a direction parallel to a surface supporting the substrate WF where the exposed resist film PR is formed. The supporting device 100 may be positioned in a direction in which the heating part 200 and the cooling part 300 move, and here, the supporting device 100 may be stopped (e.g., in a fixed position). Accordingly, the supporting device 100 may perform a relative movement to the heating part 200 and the cooling part 300, and the relative movement may be referred to as the first relative movement W1. The heating part 200 and the cooling part 300 may perform the first relative movement W1 in the x-axis direction which is a direction parallel to a surface supporting the substrate WF from position P1 of an edge (that is, an edge of the cooling part 300) farther from the supporting device 100 among those thereof.

In an example, the heating part 200 may be in a turned-on state during the first relative movement W1 to the supporting device 100. The turned-on heating part 200 may apply heat energy to the substrate WF in a position of overlapping with the supporting device 100. In addition, the cooling part 300 may be in a state of spraying the gas G during the first relative movement W1 to the supporting device 100. The cooling part 300 spraying the gas G may cool the substrate WF in a position of overlapping with the supporting device 100.

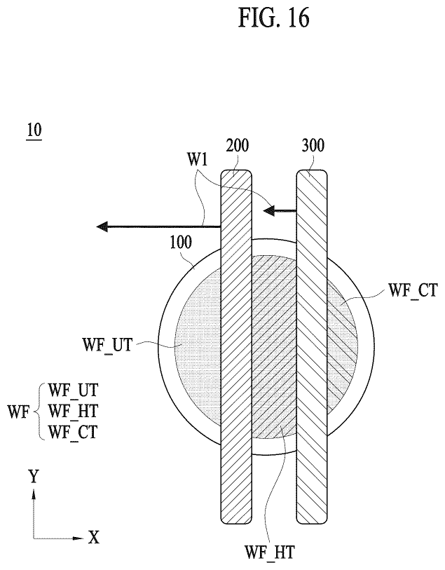

FIG. 16 is a top view illustrating the heat treatment apparatus 10 according to the second example embodiment of the present disclosure and showing a state while the substrate WF passes the heating part 200 and the cooling part 300.

In an example, the heating part 200 and the cooling part 300 may pass the supporting device 100 supporting the substrate WF. The heating part 200 may apply heat energy to the substrate WF while passing the supporting device 100. The heating part 200 may gradually increase an area to which heat energy is applied in the substrate WF during the first relative movement W1. In addition, the supporting device 100 passed by the heating part 200 may be passed by the cooling part 300. The cooling part 300 may cool the substrate WF to which heat energy is applied by the heating part 200. The cooling part 300 may gradually increase a cooled area in the substrate WF to which heat energy is previously applied by the heating part 200 during the first relative movement W1.

In an example, while the heating part 200 and the cooling part 300 perform the first relative movement W1 with respect to the supporting device 100, the substrate WF may be divided into the cooled portion WF_CT that has been heated and cooled by the heating part 200 and the cooling part 300, the heated portion WF_HT that has been heated by the heating part 200 alone, and the untreated portion WF_UT that the heating part 200 and the cooling part 300 have not yet reached.

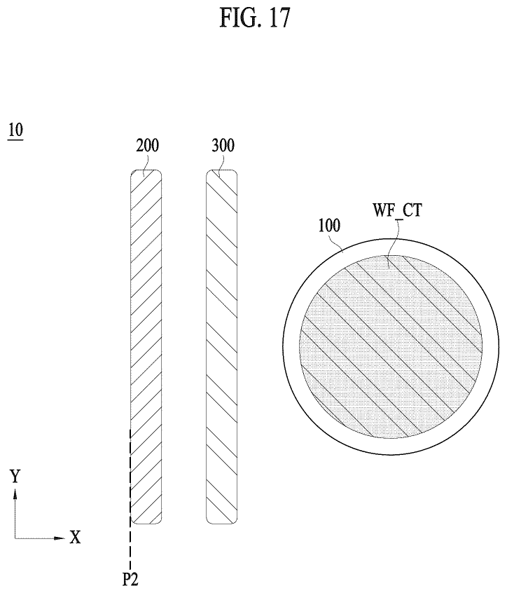

FIG. 17 is a top view illustrating the heat treatment apparatus 10 according to the second example embodiment of the present disclosure and showing a state after the substrate WF passes the heating part 200 and the cooling part 300 (e.g., after the heating part 200 and the cooling part 300 pass the substrate WF).

In an example, the heating part 200 and the cooling part 300 may perform the first relative movement W1 in the x-axis direction which is a direction parallel to a surface supporting the substrate WF at least until an entire area of the exposed resist film PR formed on the substrate WF is passed and an edge (that is, an edge of the heating part 200) farther from the supporting device 100 among those of the heating part 200 and the cooling part 300 reaches position P2. For example, after the heating part 200 and the cooling part 300 pass the substrate WF but before the heating part 200 and the cooling part 300 repass the substrate WF, the left edge of the heating part 200 as shown in FIG. 17 is the edge that is farthest from the supporting device 100. Meanwhile, the first relative movement W1 here may represent that the heating part 200 and the cooling part 300 perform a first relative movement W1 from a first position at which a far edge of the cooling part 300 is at the position P1 to a second position at which a far edge of the heating part 200 is at the position P2.

In an example, when the edge of the heating part 200 reaches position P2 through the process described above, the heating part 200 and the cooling part 300 may stop the first relative movement W1 to the supporting device 100. When the first relative movement W1 is stopped, the heating part 200 may become in a turned-off state, and the cooling part 300 may become in a state of not spraying the gas G.

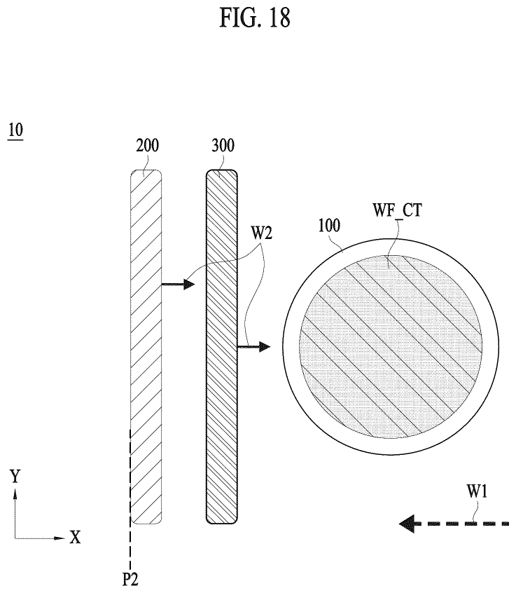

FIG. 18 is a top view illustrating the heat treatment apparatus 10 according to the second example embodiment of the present disclosure and showing a state before the substrate WF repasses the heating part 200 and the cooling part 300.

In an example, the heating part 200 and the cooling part 300 may perform the second relative movement W2 in an opposite direction to the first relative movement W1. As the heating part 200 and the cooling part 300 perform the first relative movement W1 and then the second relative movement W2 in the opposite direction, the heating part 200 and the cooling part 300 may perform the relative reciprocating movement W1 and W2 with respect to the supporting device 100. For example, as the heating part 200 and the cooling part 300 move and the supporting device 100 is stopped, the heating part 200 and the cooling part 300 may perform the second relative movement W2 in the +x-axis direction which is opposite to the −x-axis direction, the direction of the first relative direction W1. Meanwhile, the second relative movement W2 may represent that the heating part 200 and the cooling part 300 perform a second relative movement W1 from the second position at which a far edge of the heating part 200 is at the position P2 back to the first position at which a far edge of the cooling part 300 is at the position P1.

In an example, the heating part 200 of this case may be in a turned-off state during the second relative movement W2 with respect to the supporting device 100. The turned-off heating part 200 may not apply heat energy to the substrate WF supported by the supporting device 100. In addition, the cooling part 300 may be in a state of spraying the gas G during the second relative movement W2 to the supporting device 100. The cooling part 300 spraying the gas G may cool the substrate WF in a position at which the cooling part 300 overlaps with the supporting device 100.

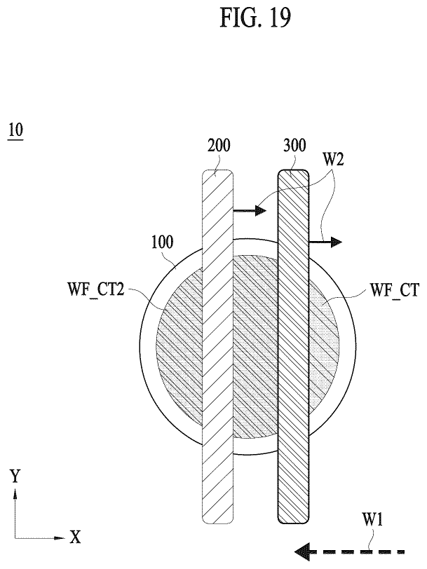

FIG. 19 is a top view illustrating the heat treatment apparatus 10 according to the second example embodiment of the present disclosure and showing a state while the substrate WF repasses the heating part 200 and the cooling part 300.

In an example, the cooling part 300 may pass the supporting device 100 supporting the substrate WF. The cooling part 300 may cool the substrate WF. The cooling part 300 may gradually increase a cooled area in the substrate WF to which heat energy is previously applied by the heating part 200 during the second relative movement W2. In addition, the supporting device 100 passed by the cooling part 300 may then be passed by the heating part 200, and the heating part 200 in the turned-off state may not apply heat energy to the substrate WF.

In an example, while the heating part 200 and the cooling part 300 perform the second relative movement W2 to the supporting device 100, the substrate WF may be divided into the cooled portion WF_CT which has not yet been recooled by the cooling part 300 after the heating part 200 applies heat energy during the first relative movement W1 and the additionally cooled portion WF_CT2 which has been recooled by the cooling part 300 during the second relative movement W2.

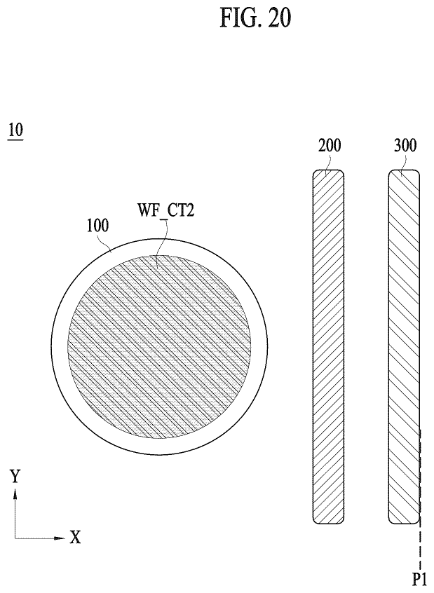

FIG. 20 is a top view illustrating the heat treatment apparatus 10 according to the second example embodiment of the present disclosure and showing a state after the substrate WF repasses the heating part 200 and the cooling part 300.

In an example, the heating part 200 and the cooling part 300 may perform the second relative movement W2 in the positive x-axis direction which is a direction parallel to a surface supporting the substrate WF at least until an entire area of the exposed resist film PR formed on the substrate WF is repassed and an edge (that is, an edge of the cooling part 300) farther from the supporting device 100 among those of the heating part 200 and the cooling part 300 reaches position P1.

Specifically, the second relative movement W2 of the supporting device 100 and the cooling part 300 may continue at least until the entire area of the exposed resist film PR is cooled by the cooling part 300.

In an example, when the edge (that is, the edge of the cooling part 300) farther from the supporting device 100 among those of the heating part 200 and the cooling part 300 reaches position P1 through the process described above, the heating part 200 and the cooling part 300 may stop the second relative movement W2 with respect to the supporting device 100. When the second relative movement W2 is stopped, the heating part 200 may maintain the turned-off state, and the cooling part 300 may become in a state of not spraying the gas G.

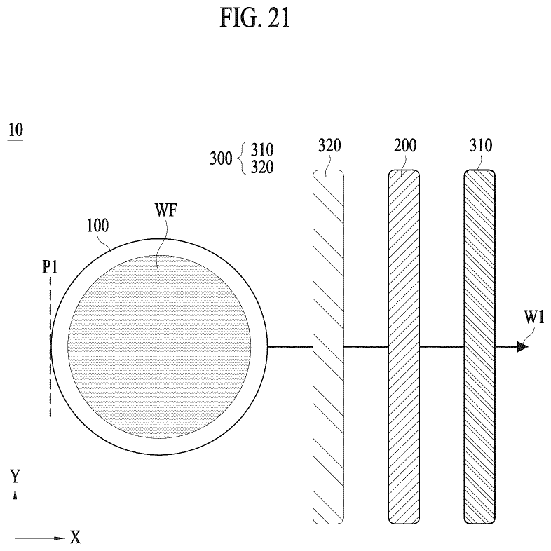

Hereinafter, through FIGS. 21 to 32, the heat treatment apparatus 10 according to a third example embodiment in which a plurality of the cooling parts 300 are provided is described. FIGS. 21 to 32 illustrate that the supporting device 100 moves and the heating part 200 and the cooling part 300 do not move as one example of a relative movement, but it may be apparent to those skilled in the art that the heating part 200 and the cooling part 300 may move and the supporting device 100 does not move as one example of a relative movement even though not illustrated as described above. Further, descriptions here may refer to the descriptions above of the heat treatment apparatus 10 according to the first example embodiment or the second example embodiment unless contradicted.

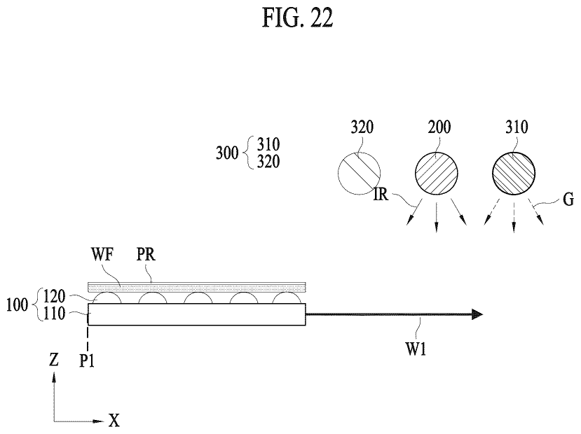

FIG. 21 is a top view illustrating the heat treatment apparatus 10 according to the third example embodiment of the present disclosure and showing a state before the substrate WF passes the heating part 200 and the cooling part 300. FIG. 22 is a side view illustrating the heat treatment apparatus 10 according to the third example embodiment of the present disclosure and showing a state before the substrate WF passes the heating part 200 and the cooling part 300.

In an example, the plurality of the cooling parts 300 may include a first cooling part 310 disposed in front of the heating part 200 (that is, in the +x direction in FIG. 21) in the direction of the first relative movement W1 and a second cooling part 320 disposed behind the heating part 200 (that is, in the −x direction in FIG. 21). Meanwhile, one or a plurality of the first cooling parts 310 and the second cooling parts 320 may be provided each independently. Through this structure, the cooling of the substrate WF may be more precisely controlled.

In an example, the first cooling part 310 and the second cooling part 320 may perform identical relative movements to the relative movement of the heating part 200. In addition, the first cooling part 310 and the second cooling part 320 may be positioned alongside the heating part 200 and may be spaced apart from the heating part 200 by a predetermined distance in the direction of the first relative movement W1. Further, a distance between the first cooling part 310 and the heating part 200 may be identical to a distance between the second cooling part 320 and the heating part 200.

In an example, the first cooling part 310 and the second cooling part 320 may refer to the features of the cooling part 300 described above. The heat treatment apparatus 10 may include the heating part 200 and the cooling part 300 disposed in a direction in which the supporting device 100 moves, and the cooling part 300 may include the first cooling part 310 and the second cooling part 320. Here, the first cooling part 310 and the second cooling part 320 may be stopped as well as the heating part 200. Accordingly, the supporting device 100 may move relative to the heating part 200 and the cooling part 300. Specifically, the supporting device 100 may move relative to the first cooling part 310 and the second cooling part 320. The relative movement may be referred to as the first relative movement W1. The supporting device 100 may perform the first relative movement W1 in the x-axis direction which is a direction parallel to a surface supporting the substrate WF from position P1 of an edge of the supporting device 100 that is farthest from the heating part 200 and the cooling part 300.

In an example, the heating part 200 of this case may be in a turned-on state during the first relative movement W1 with respect to the supporting device 100. In addition, the first cooling part 310 may be in a state of spraying the gas G during the first relative movement W1 with respect to the supporting device 100. In other words, the first cooling part 310 may cool the substrate WF during the first relative movement W1 with respect to the supporting device 100. Further, the second cooling part 320 may be in a state of not spraying the gas G during the first relative movement W1 with respect to the supporting device 100.

In an example, each type of the gas G sprayed from the first cooling part 310 and the gas G sprayed from the second cooling part 320 may be independent, and each temperature and flow rate of the gas G sprayed from the first cooling part 310 and the second cooling part 320 may also be set independently.

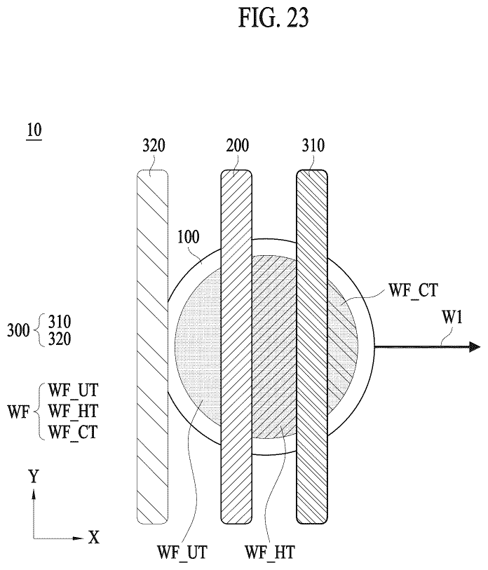

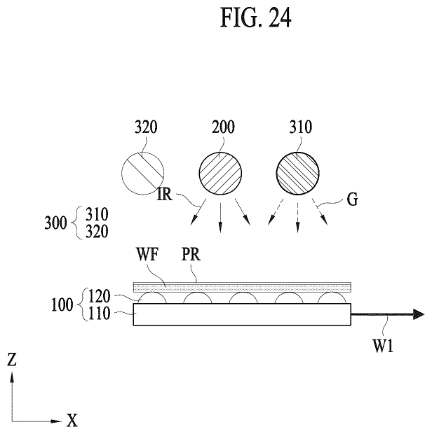

FIG. 23 is a top view illustrating the heat treatment apparatus 10 according to the third example embodiment of the present disclosure and showing a state while the substrate WF passes the heating part 200 and the cooling part 300. FIG. 24 is a side view illustrating the heat treatment apparatus 10 according to the third example embodiment of the present disclosure and showing a state while the substrate WF passes the heating part 200 and the cooling part 300.

In an example, the supporting device 100 supporting the substrate WF may pass the second cooling part 320. The second cooling part 320 may not cool the substrate WF during the first relative movement W1 with respect to the supporting device 100. In addition, the supporting device 100 after passing the second cooling part 320 may pass the heating part 200, and the heating part 200 may apply heat energy to the substrate WF. The heating part 200 may gradually increase an area to which heat energy is applied in the substrate WF during the first relative movement W1. Further, the supporting device 100 after passing the heating part 200 may pass the first cooling part 310. The first cooling part 310 may cool the substrate WF to which heat energy is applied by the heating part 200. The first cooling part 310 may gradually increase a cooled area in the substrate WF to which heat energy is previously applied by the heating part 200 during the first relative movement W1.

In an example, while the supporting device 100 performs the first relative movement W1 with respect to the heating part 200 and the cooling part 300, the substrate WF may be divided into the cooled portion WF_CT that has passed both the heating part 200 and the first cooling part 310, the heated portion WF_HT that has passed the heating part 200 alone, and the untreated portion WF_UT that has not yet reached the heating part 200 and the first cooling part 310.

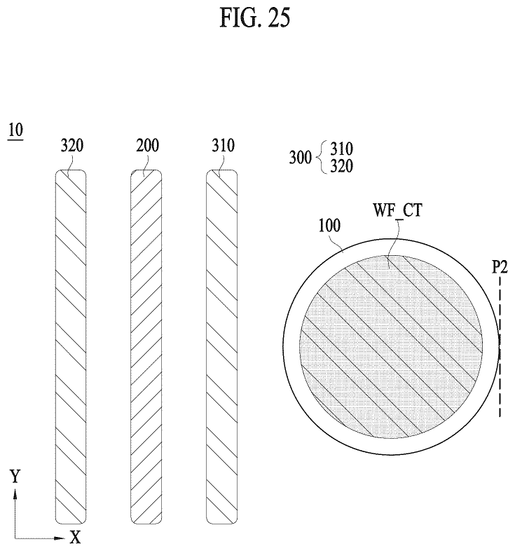

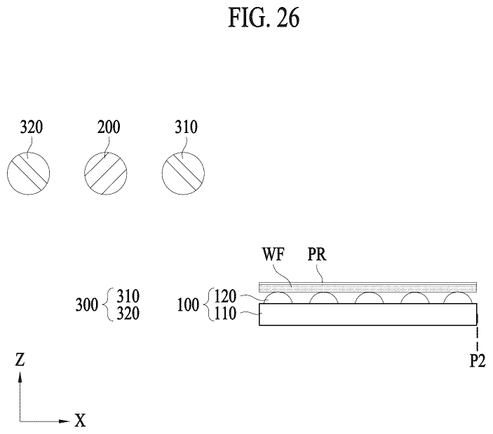

FIG. 25 is a top view illustrating the heat treatment apparatus 10 according to the third example embodiment of the present disclosure and showing a state after the substrate WF passes the heating part 200 and the cooling part 300. FIG. 26 is a side view illustrating the heat treatment apparatus 10 according to the third example embodiment of the present disclosure and showing a state after the substrate WF passes the heating part 200 and the cooling part 300.

In an example, the supporting device 100 may perform the first relative movement W1 in the x-axis direction which is a direction parallel to a surface supporting the substrate WF at least until an entire area of the exposed resist film PR formed on the substrate WF passes the heating part 200 and the cooling part 300 including the first cooling part 310 and the second cooling part 320 and an edge of the supporting device 100 reaches position P2.

Specifically, the first relative movement W1 between the supporting device 100 and the heating part 200 may continue at least until heat energy by the heating part 200 is applied to the entire area of the exposed resist film PR. In addition, the first relative movement W1 between the supporting device 100 and the first cooling part 310 may continue at least until the entire area of the exposed resist film PR is cooled by the first cooling part 310.

In an example, when the edge of the supporting device 100 reaches position P2 through the process described above, the supporting device 100 may stop the first relative movement W1 with respect to the heating part 200 and the cooling part 300 including the first cooling part 310 and the second cooling part 320. When the first relative movement W1 is stopped, the heating part 200 may become in a turned-off state, and the first cooling part 310 may become in a state of not spraying the gas G. Meanwhile, the second cooling part 320 may be maintained in a state of not spraying the gas G during the first relative movement W1 and until after the first relative movement W1 is stopped.

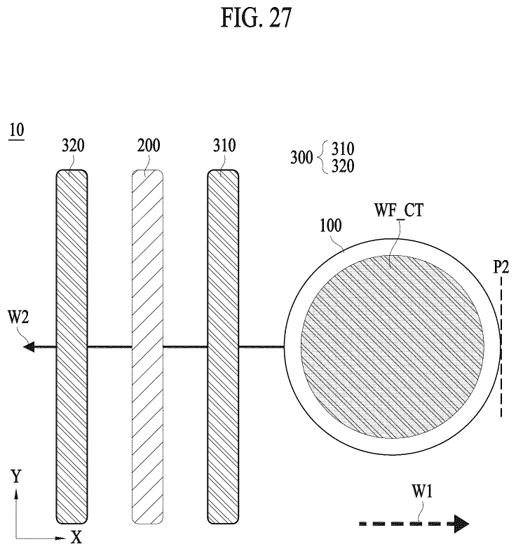

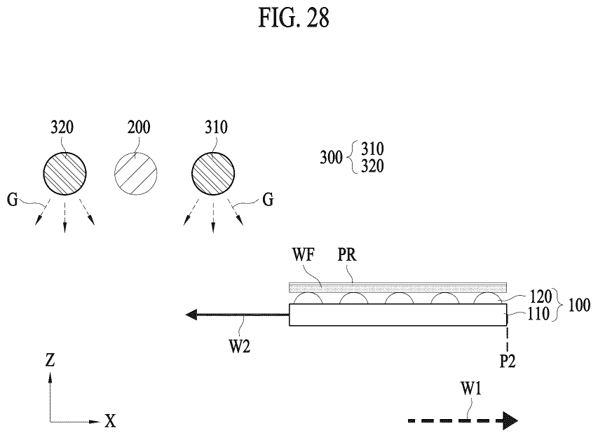

FIG. 27 is a top view illustrating the heat treatment apparatus 10 according to the third example embodiment of the present disclosure and showing a state before the substrate WF repasses the heating part 200 and the cooling part 300. FIG. 28 is a side view illustrating the heat treatment apparatus 10 according to the third example embodiment of the present disclosure and showing a state before the substrate WF repasses the heating part 200 and the cooling part 300.

In an example, the supporting device 100 may perform the second relative movement W2 in an opposite direction to the first relative movement W1. The heating part 200 may be in a turned-off state during the second relative movement W2 with respect to the supporting device 100. The turned-off heating part 200 may not apply heat energy to the substrate WF supported by the supporting device 100.

In an example, the first cooling part 310 and the second cooling part 320 may both be in a state of spraying the gas G during the second relative movement W2 with respect to the supporting device 100. The first cooling part 310 and the second cooling part 320 spraying the gas G may cool the substrate WF in a position at which the first cooling part 310 and the second cooling part 320 overlap with the supporting device 100. Meanwhile, the first cooling part 310 and the second cooling part 320 of this case may cool the substrate WF to lower a surface temperature of the substrate WF.

In an example, the first cooling part 310 may cool substrate WF during both the first relative movement W1 and the second relative movement W2 with respect to the supporting device 100. The second cooling part 320 may not cool the substrate WF during the first relative movement W1 with respect to the supporting device 100 but may cool the substrate WF during the second relative movement W2 with respect to the supporting device 100.

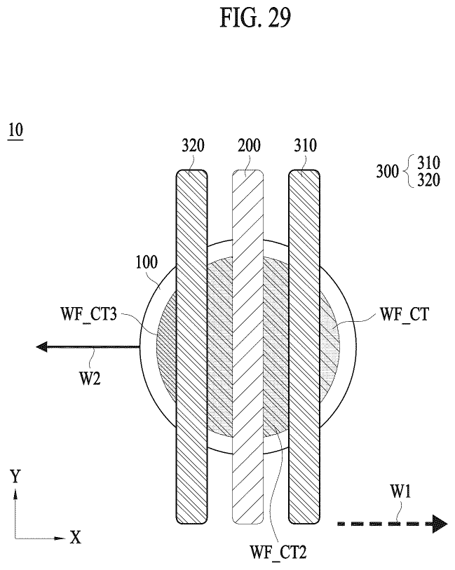

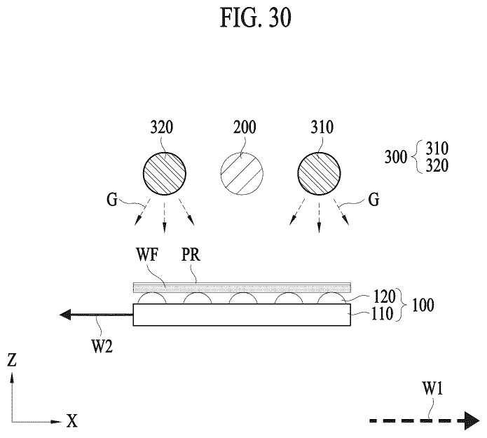

FIG. 29 is a top view illustrating the heat treatment apparatus 10 according to the third example embodiment of the present disclosure and showing a state while the substrate WF repasses the heating part 200 and the cooling part 300. FIG. 30 is a side view illustrating the heat treatment apparatus 10 according to the third example embodiment of the present disclosure and showing a state while the substrate WF repasses the heating part 200 and the cooling part 300.

In an example, the supporting device 100 supporting the substrate WF may pass the first cooling part 310 and the second cooling part 320. The first cooling part 310 and the second cooling part 320 may cool the substrate WF.

In an example, the first cooling part 310 may gradually increase a cooled area in the substrate WF to which heat energy is previously applied by the heating part 200 during the second relative movement W2. In addition, the supporting device 100 after passing the first cooling part 310 may pass the heating part 200, and the heating part 200 in the turned-off state may not apply heat energy to the substrate WF.

In an example, the second cooling part 320 may gradually increase an additionally cooled area in the substrate WF that is previously and primarily cooled by the first cooling part 310 during the second relative movement W2.

In an example, while the supporting device 100 performs the second relative movement W2 with respect to the heating part 200 and the cooling part 300 including the first cooling part 310 and the second cooling part 320, the substrate WF may be divided into the cooled portion WF_CT that has been cooled by the first cooling part 310 after the heating part 200 applies heat energy during the first relative movement W1 but has not yet been recooled, the additionally cooled portion WF_CT2 that has been recooled by the first cooling part 310 during the second relative movement W2 but has not yet been recooled by the second cooling part 320, and a further additionally cooled portion WF_CT3 that has been recooled by both the first cooling part 310 and the second cooling part 320 during the second relative movement W2.

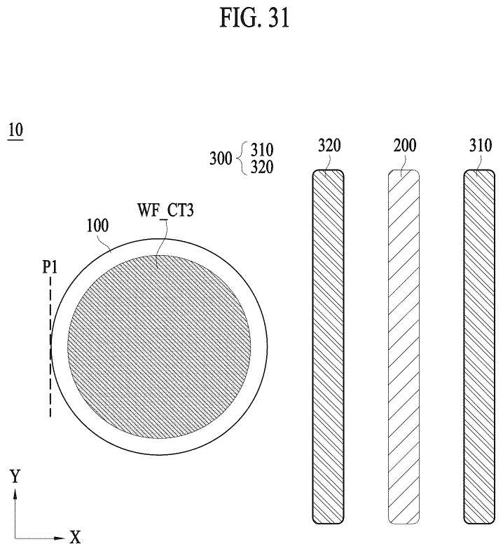

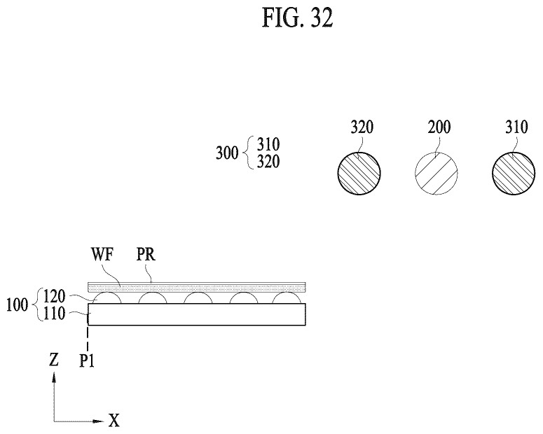

FIG. 31 is a top view illustrating the heat treatment apparatus 10 according to the third example embodiment of the present disclosure and showing a state after the substrate WF repasses the heating part 200 and the cooling part 300. FIG. 32 is a side view illustrating the heat treatment apparatus 10 according to the third example embodiment of the present disclosure and showing a state after the substrate WF repasses the heating part 200 and the cooling part 300.

In an example, the supporting device 100 may perform the second relative movement W2 in the x-axis direction which is a direction parallel to a surface supporting the substrate WF at least until an entire area of the exposed resist film PR formed on the substrate WF repasses the heating part 200 and the cooling part 300 including the first cooling part 310 and the second cooling part 320 and an edge of the supporting device 100 reaches position P1.

In an example, the second relative movement W2 between the supporting device 100 and the cooling part 300 including the first cooling part 310 and the second cooling part 320 may continue at least until the entire area of the exposed resist film PR is cooled by the first cooling part 310 and the second cooling part 320.

In an example, when the edge of the supporting device 100 reaches position P1 through the process described above, the supporting device 100 may stop the second relative movement W2 with respect to the heating part 200 and the cooling part 300. When the second relative movement W2 is stopped, the heating part 200 may maintain the turned-off state, and the first cooling part 310 and the second cooling part 320 may become in a state of not spraying the gas G.

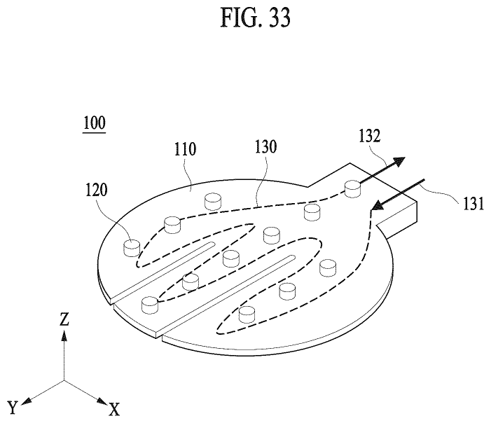

FIG. 33 illustrates the supporting device 100 according to an example embodiment of the present disclosure. In an example, the supporting device 100 may include the supporting plate 110 equipped with a flow path 130 and the protrusion 120 protruding on the supporting plate 110. The substrate WF may be supported by the supporting device 100 but supported on the protrusion 120 and thus may be spaced apart from the supporting plate 110 by a predetermined distance. A fluid may circulate in the flow path 130 and cool the substrate WF. The flow path 130 may be built in the supporting device 110 so that the fluid may circulate throughout the supporting plate 110. The flow path 130 illustrated in FIG. 33 is one example but is not limited thereto and may be built in the supporting plate 110 in various forms.

In an example, the flow path 130 may include a flow path entrance 131 connected to the outside and a flow path exit 132. A fluid may enter into the flow path 130 through the flow path entrance 131 and may be released from the flow path 130 through the flow path exit 132. Though not illustrated in the drawing, the flow path entrance 131 and the flow path exit 132 may be connected to each other at a position external to the supporting device 100, and accordingly, the fluid may circulate. In addition, a heat discharge part (e.g., a heat sink, not shown) may be included between the flow path entrance 131 and the flow path exit 132 in a position external to the supporting device 100, and as the heat discharge part discharges heat transferred from the substrate WF, a circulation structure may be formed in the flow path 130. For example, the fluid may be, but not limited to, a coolant. In addition, a pump may be connected to the flow path 130, and the fluid may pass through the flow path 130 by a pressure applied by the pump.

In an example, the fluid circulating in the flow path 130 may have heat energy transferred from the substrate WF mainly by convection and radiation. Further, a temperature of the fluid may be changed to adjust a cooling speed of the substrate WF.

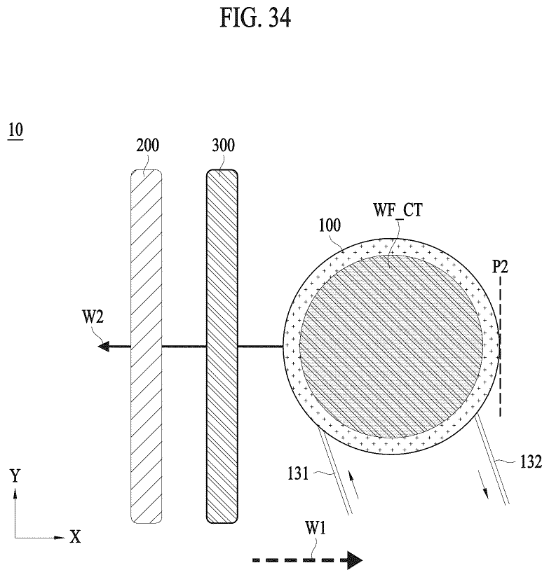

Hereinafter, through FIGS. 34 to 38, the heat treatment apparatus 10 according to a fourth example embodiment in which the supporting device 100, including the supporting plate 110 equipped with the flow path 130 and the protrusion 120, is provided is described. FIGS. 34 to 38 illustrate that the supporting device 100 moves and the heating part 200 and the cooling part 300 do not move as one example of a relative movement, but it may be apparent to those skilled in the art that the heating part 200 and the cooling part 300 may move and the supporting device 100 may not move as one example of a relative movement even though not illustrated as described above. Further, descriptions here may refer to the descriptions above of the heat treatment apparatus 10 according to the first example embodiment, the second example embodiment, or the third example embodiment unless contradicted.

FIG. 34 is a top view illustrating the heat treatment apparatus 10 according to the fourth example embodiment of the present disclosure and showing a state after the substrate WF has passed the heating part 200 and the cooling part 300, but before the substrate WF repasses the heating part 200 and the cooling part 300.

In an example, a fluid may enter into the flow path 130 built in the supporting plate 110 through the flow path entrance 131 and may be released from the flow path 130 through the flow path exit 132. The supporting device 100 may perform the second relative movement W2 in an opposite direction to the first relative movement W1. In this case, the heating part 200 may be in a turned-off state during the second relative movement W2 with respect to the supporting device 100. The turned-off heating part 200 may not apply heat energy to the substrate WF supported by the supporting device 100.

In an example, a fluid may circulate in the flow path 130 and cool the substrate WF during the second relative movement W2 between the supporting device 100 and the heating part 200. In contrast, a fluid may not circulate in the flow path 130 and may not cool the substrate WF during the first relative movement W1 between the supporting device 100 and the heating part 200. When circulating a fluid in the flow path 130 during the second relative movement W2 between the supporting device 100 and the heating part 200, the substrate WF may be more rapidly cooled, thereby controlling a pattern pitch size of a resist pattern. In addition, by circulating a fluid in the flow path 130 during the second relative movement W2 of the supporting device 100 and the heating part 200, an impact of the supporting plate 110 heated due to the heating part 200 during the first relative movement W1 of the supporting device 100 and the heating part 200 on a surface temperature of the substrate WF may be minimized.

In an example, the cooling part 300 may be in a state of spraying the gas G during the second relative movement W2 with respect to the supporting device 100. The cooling part 300 spraying the gas G may cool the substrate WF in a position of overlapping with the supporting device 100. Meanwhile, in this case, the cooling part 300 may cool the substrate WF to lower a surface temperature of the substrate WF.

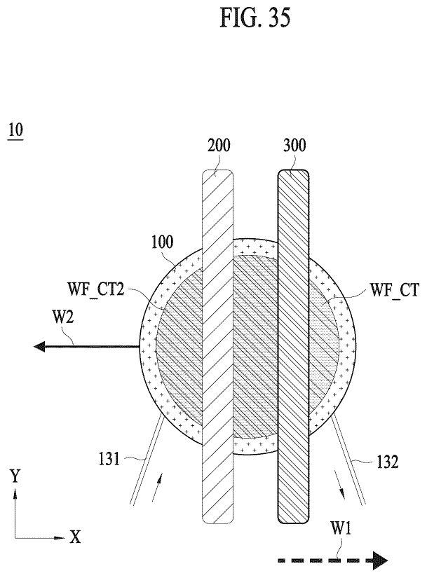

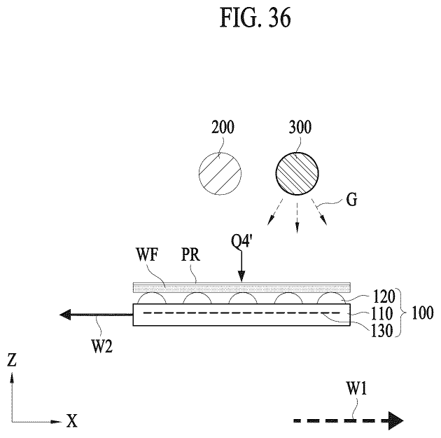

FIG. 35 is a top view illustrating the heat treatment apparatus 10 according to the fourth example embodiment of the present disclosure and showing a state while the substrate WF repasses the heating part 200 and the cooling part 300. FIG. 36 is a side view illustrating the heat treatment apparatus 10 according to the fourth example embodiment of the present disclosure and showing a state while the substrate WF repasses the heating part 200 and the cooling part 300.

In an example, the supporting device 100 supporting the substrate WF may pass the cooling part 300. The cooling part 300 may cool the substrate WF and may gradually increase a cooled area in the substrate WF to which heat energy is previously applied by the heating part 200 during the second relative movement W2.

In an example, while the supporting device 100 performs the second relative movement W2 with respect to the heating part 200 and the cooling part 300, the substrate WF may be divided into the cooled portion WF_CT that has been cooled by the cooling part 300 after the heating part 200 applies heat energy during the first relative movement W1 but has not yet been recooled by the cooling part 300 during the second relative movement W2, and the additionally cooled portion WF_CT2 that has been recooled by the cooling part 300 during the second relative movement W2.

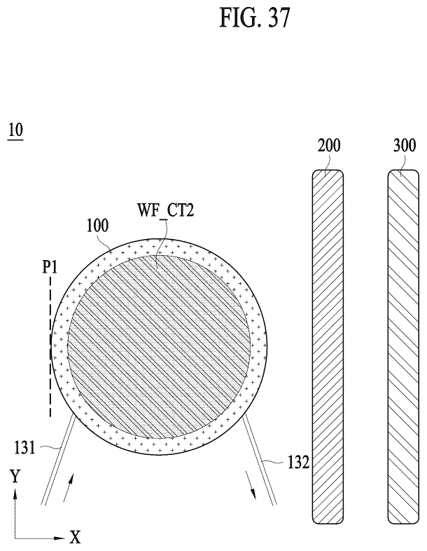

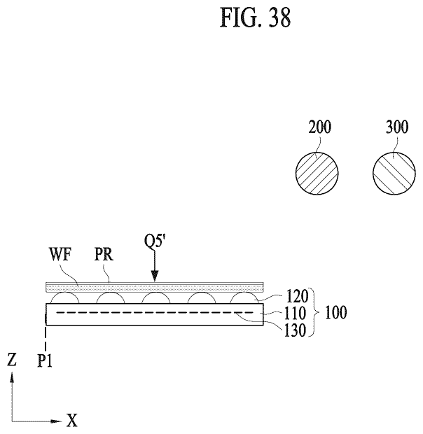

FIG. 37 is a top view illustrating the heat treatment apparatus 10 according to the fourth example embodiment of the present disclosure and showing a state after the substrate WF repasses the heating part 200 and the cooling part 300. FIG. 38 is a side view illustrating the heat treatment apparatus 10 according to the fourth example embodiment of the present disclosure and showing a state after the substrate WF repasses the heating part 200 and the cooling part 300.

In an example, the supporting device 100 may perform the second relative movement W2 in the x-axis direction which is a direction parallel to a surface supporting the substrate WF at least until an entire area of the exposed resist film PR formed on the substrate WF repasses the heating part 200 and the cooling part 300 and an edge of the supporting device 100 reaches position P1.

In an example, the second relative movement W2 of the supporting device 100 and the cooling part 300 may continue at least until the entire area of the exposed resist film PR is cooled by the first cooling part 310 and the second cooling part 320.

In an example, when the edge of the supporting device 100 reaches position P1 through the process described above, the supporting device 100 may stop the second relative movement W2 with respect to the heating part 200 and the cooling part 300. When the second relative movement W2 is stopped, the heating part 200 may maintain the turned-off state, and the cooling part 300 may become in a state of not spraying the gas G.

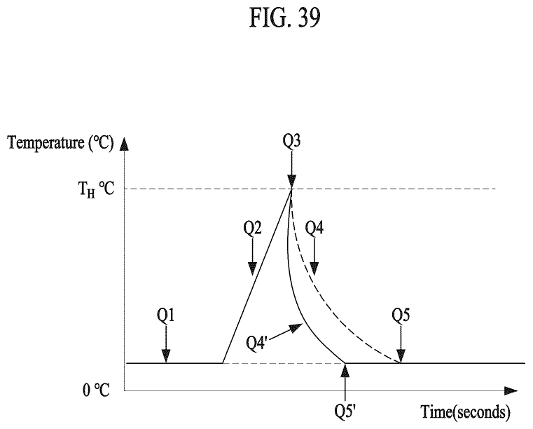

FIG. 39 may be a graph showing a temperature at each time point after passing and repassing the heating part 200 and the cooling part 300 for a point on a substrate WF surface in the fourth example embodiment of the present disclosure and may be a graph showing, for example, a center point temperature of the substrate WF surface. The graph of FIG. 39 may refer to the descriptions of the graph of FIG. 13 unless contradicted.

Referring to FIGS. 39, Q1, Q2, and Q3 are identical to those in the descriptions of the graph of FIG. 13. Q4′ represents a temperature of a point on the surface in a state while the substrate WF repasses the heating part 200 and the cooling part 300 as a fluid circulates in the flow path 130 (see FIG. 36). Q5′ represents a temperature of a point on the surface in a state after the substrate WF repasses the heating part 200 and the cooling part 300 as a fluid circulates in the flow path 130 (see FIG. 38).

Referring to FIG. 39, a fluid may circulate in the flow path 130 and additionally cool the substrate WF, and simultaneously, may relieve overheating of the supporting plate 110 and more rapidly lower a surface temperature of the substrate WF. Through this, a pattern pitch size of a resist pattern may be controlled.

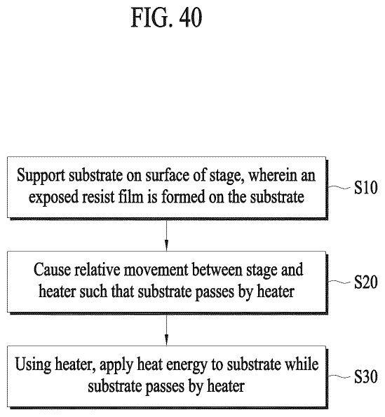

FIG. 40 shows a method of heat treating a substrate according to an example embodiment.

Referring to FIG. 40, at step S10, a substrate is supported on a surface of a stage, wherein an exposed resist film is formed on the substrate. At step S20, a relative movement is caused between the stage and a heater. The relative movement may be parallel to the surface of the stage such that the substrate passes by the heater. At step S30, during the relative movement, the heater applies heat to the substrate as the substrate passes by the heater.

While example embodiments of the present disclosure are described above with reference to the attached drawings, the present disclosure is not limited to the example embodiments and may be implemented in various different forms, and it may be understood by those of ordinary skill in the art that the present disclosure may be implemented in a different specific form without the technical spirit or essential features thereof changed. Therefore, the above-described example embodiments are to be understood as examples in every aspect, not as limited thereto.

1. A heat treatment apparatus comprising:
a stage having a surface configured to support a substrate, wherein an exposed resist film is formed on the substrate; and
a heater spaced apart from the stage in a direction perpendicular to the surface of the stage, wherein the heater is configured such that a relative movement occurs between the stage and the heater, the relative movement being parallel to the surface of the stage,
wherein the heater is configured to apply heat energy to the substrate in a position at which the heater overlaps with the stage in the direction perpendicular to the surface of the stage during the relative movement between the stage and the heater.

2. The heat treatment apparatus of claim 1, wherein a length of the heater is larger than a diameter of the substrate in a direction perpendicular to the direction of relative movement.

3. The heat treatment apparatus of claim 1, wherein at least one of the stage and the heater is configured to move relative to the other one of the stage and the heater such that heat energy by the heater is applied to an entire area of the exposed resist film.

4. The heat treatment apparatus of claim 1, further comprising a cooler spaced apart from the stage in the direction perpendicular to the surface of the stage, the cooler being configured to cool the substrate to which heat energy is applied by the heater during a relative movement between the stage and the cooler in the direction parallel to the surface of the stage.

5. The heat treatment apparatus of claim 4, wherein the cooler is configured to cool the substrate in a position at which the cooler overlaps with the stage in the direction perpendicular to the surface of the stage while there is relative movement between the cooler and the stage.

6. The heat treatment apparatus of claim 4, wherein the cooler is one of a plurality of coolers, and the heater is disposed between adjacent coolers of the plurality of coolers.

7. The heat treatment apparatus of claim 4, wherein the cooler is configured to cool the substrate by spraying gas.

8. The heat treatment apparatus of claim 1, wherein the stage includes:
a supporting plate equipped with a flow path; and
a protrusion protruding from the supporting plate, and
wherein the protrusion is configured to support the substrate such that the substrate is spaced apart from the supporting plate by a predetermined distance.

9. The heat treatment apparatus of claim 8, further comprising a pump configured to circulate a fluid in the flow path and cool the substrate.

10. A heat treatment apparatus comprising:
a stage having a surface configured to support a substrate, wherein an exposed resist film is formed on the substrate;
a heater spaced apart from the stage in a direction perpendicular to the surface of the stage; and
a transfer device configured to cause a relative reciprocating movement between the stage and the heater,
wherein the heater is configured such that the relative reciprocating movement occurs between the stage and the heater, the relative reciprocating movement being parallel to the surface of the stage,
wherein the relative reciprocating movement includes a first relative movement and a second relative movement in an opposite direction to the first relative movement, and
wherein the heater is configured to apply heat energy to the substrate in a position at which the heater overlaps with the stage in the direction perpendicular to the surface of the stage during the relative reciprocating movement between the stage and the heater.

11. The heat treatment apparatus of claim 10, wherein the transfer device is configured to cause the first relative movement of the heater and the stage to continue until heat energy by the heater is applied to an entire area of the exposed resist film.

12. The heat treatment apparatus of claim 10, wherein the transfer device is configured to cause the relative reciprocating movement between the stage and the heater to be executed a plurality of times.

13. The heat treatment apparatus of claim 10, further comprising a cooler spaced apart from the stage in the direction perpendicular to the surface of the stage, the cooler being configured to cool the substrate to which heat energy is applied by the heater during a relative reciprocating movement between the stage and the cooler in the direction parallel to the surface of the stage.
wherein the relative reciprocating movement between the stage and the cooler is identical to the relative reciprocating movement between the stage and the heater.

14. The heat treatment apparatus of claim 13, wherein the cooler is positioned alongside the heater in the direction parallel to the surface of the stage.

15. The heat treatment apparatus of claim 14, wherein the cooler is configured to cool the substrate in a position at which the cooler overlaps with the stage in the direction perpendicular to the surface of the stage during at least one of the first relative movement and the second relative movement, and
wherein the heater is configured not to apply heat energy to the substrate during the second relative movement.

16. The heat treatment apparatus of claim 15, wherein the cooler is one of a plurality of coolers, the plurality of coolers including a first cooler disposed in front of the heater and a second cooler disposed behind the heater based on a direction of the first relative movement.

17. The heat treatment apparatus of claim 16, wherein the first cooler is configured to cool the substrate during the first relative movement and the second relative movement, and
wherein the second cooler is configured to cool the substrate during the second relative movement.

18. The heat treatment apparatus of claim 15, wherein the stage includes:
a supporting plate equipped with a flow path; and
a protrusion protruding on the supporting plate, and
wherein the supporting plate is configured to circulate a fluid in the flow path that cools the substrate during the second relative movement between the stage and the heater.

19. The heat treatment apparatus of claim 18, wherein the protrusion is configured to support the substrate spaced apart from the supporting plate by a predetermined distance.

20. A heat treatment apparatus comprising:
a stage having a surface configured to support a substrate, wherein an exposed resist film is formed on the substrate;
a heater spaced apart from the stage in a direction perpendicular to the surface of the stage, wherein the heater is configured such that a relative reciprocating movement occurs between the stage and the heater, the relative reciprocating movement being in a direction parallel to the surface of the stage; and
a cooler spaced apart from the stage in the direction perpendicular to the surface of the stage, the cooler being configured to cool the substrate to which heat energy is applied by the heater during a relative reciprocating movement between the stage and the cooler in the direction parallel to the surface of the stage,
wherein the relative reciprocating movement includes a first relative movement and a second relative movement in an opposite direction to the first relative movement,
wherein the stage includes a supporting plate equipped with a flow path and a protrusion protruding on the supporting plate, and the supporting plate is configured to circulate a fluid in the flow path that cools the substrate during the second relative movement between the stage and the heater, and the protrusion is configured to support the substrate spaced apart from the supporting plate by a predetermined distance,
wherein the heater is configured to apply heat energy to the substrate in a position in which the heater is vertically aligned with the stage during the first relative movement and not to apply heat energy to the substrate during the second relative movement, and
wherein the relative reciprocating movement between the stage and the cooler is identical to the relative reciprocating movement between the stage and the heater,
wherein the cooler is positioned alongside the heater in the direction parallel to the surface of the stage, and
wherein the cooler is configured to cool the substrate in a position at which the cooler overlaps with the stage in the direction perpendicular to the surface of the stage during at least one of the first relative movement and the second relative movement.

21-26. (canceled)
